(19) United States
(12) Patent Application Publication
(10) Pub. No.: US 2024/0292557 A1
(43) Pub. Date: Aug. 29, 2024

(54) SURFACE-MOUNTED RETAINING MECHANISM FOR ELECTRONIC DEVICES

(71) Applicant: Intel Corporation, Santa Clara, CA (US)

(72) Inventors: Pharveen Parameswaran, Penang (MY); Santhosh Ap, Bangalore (IN); Poh Ling Lee, Penang (MY); Prasanna Pichumani, Bangalore (IN); Vijith Halestoph R, Bangalore (IN); Syed Bukhari Syed Shafi, Penang (MY); Anas Zakaria, Penang (MY)

(21) Appl. No.: 18/650,553

(22) Filed: Apr. 30, 2024

(51) Int. Cl. H05K 7/14

(52) U.S. Cl. CPC H05K 7/1405

(57) ABSTRACT

A surface-mounted retaining assembly is provided for retaining an electronic component. The electronic component may comprise an internal expansion card of an electronic device, and may comprise an M.2 module. The retaining assembly utilizes a spring-loaded retaining mechanism and may be bonded to a printed circuit board (PCB) via a small footprint solder pad. The retaining assembly eliminates the need for through-hole or surface-mounted standoffs, and thus increases the usable routing area on all layers. Additionally, the retaining assembly does not require a threaded component, and is suitable for low profile applications for which threaded components are infeasible.

### TECHNICAL FIELD

The disclosure is directed generally to a retaining mechanism for electronic components and, in particular, to a surface-mounted retaining mechanism for electronic device components that improves repairability and increases available circuit board space as a result of a smaller footprint and the elimination of through holes.

### BACKGROUND

Electronic devices often utilize various types of electronic components that are mechanically retained in a fixed physical relationship with other components. This may include internally-mounted expansion cards such as memory modules, graphics cards, solid state drives, etc., which may meet the M.2 specification and are thus referred to as M.2 modules. Such electronic components have corresponding connectors that are typically mounted to the printed circuit board (PCB) of the electronic device. In addition to being coupled to the PCB via this connector, the electronic components also need to be mechanically retained to the PCB in a manner that allows for their removal in the event of servicing, upgrading, replacement, etc. The conventional manner in which such electronic components are mechanically retained to an electronic device PCB are inadequate.

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the techniques discussed herein.

In the drawings, like reference characters generally refer to the same parts throughout the different views. The drawings are not necessarily to scale, emphasis instead generally being placed upon illustrating the principles of the disclosure. In the following description, reference is made to the following drawings, in which:

FIGS. 1A-1C illustrate various views of an electronic component installation implementing a retaining assembly, in accordance with the disclosure.

FIG. 2 illustrates a manufacturing procedure for a retaining assembly, in accordance with the disclosure;

FIGS. 3A-3E illustrate various views of a retaining assembly, in accordance with the disclosure;

FIGS. 4A-4B illustrate various views of a housing of a retaining assembly, in accordance with the disclosure;

FIGS. 5A-5B illustrate various views of a retaining mechanism and pin of a retaining assembly, in accordance with the disclosure;

FIGS. 6A and 6B illustrate sample dimensions of a retaining assembly, in accordance with the disclosure;

FIG. 7 illustrates the use of a PCB solder pad for a retaining assembly compared to that required for a conventional PCB mounting, in accordance with the disclosure;

FIG. 8 illustrates an electronic device, in accordance with the disclosure; and

FIG. 9 illustrates a process flow, in accordance with the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

### I. Introduction to Mechanical Retention Systems

Again, conventional mechanical retaining systems for electronic components have been inadequate. For instance, conventional retention mechanisms for M.2 modules implement through-hole M.2 standoffs or surface-mounted M.2 standoffs. However, the use of through-hole M.2 standoffs on a PCB requires a keep out zone on all layers of the PCB, and thus reduces the usable routing area on all layers. This causes layout engineers to route around the plated thru hole (PTH), resulting in a trace length increase. Additionally, surface-mounted M.2 standoffs typically utilize a threaded component. As a result, such standoffs are fragile and may become detached from the PCB during servicing due to the force needed to screw/unscrew the module, resulting in the PCB being discarded. Moreover, surface-mounted M.2 standoffs cannot be used for low-profile systems due to the insufficient thread count required to provide reliable mechanical retention. These issues are addressed via the retaining assembly as discussed herein, which may function to replace current standoffs with a surface mounted retaining assembly that uses spring-loaded mechanical retention to hold an electronic component, such as an M.2 module, in place.

### II. Installation of Electronic Components Using a Retaining Assembly

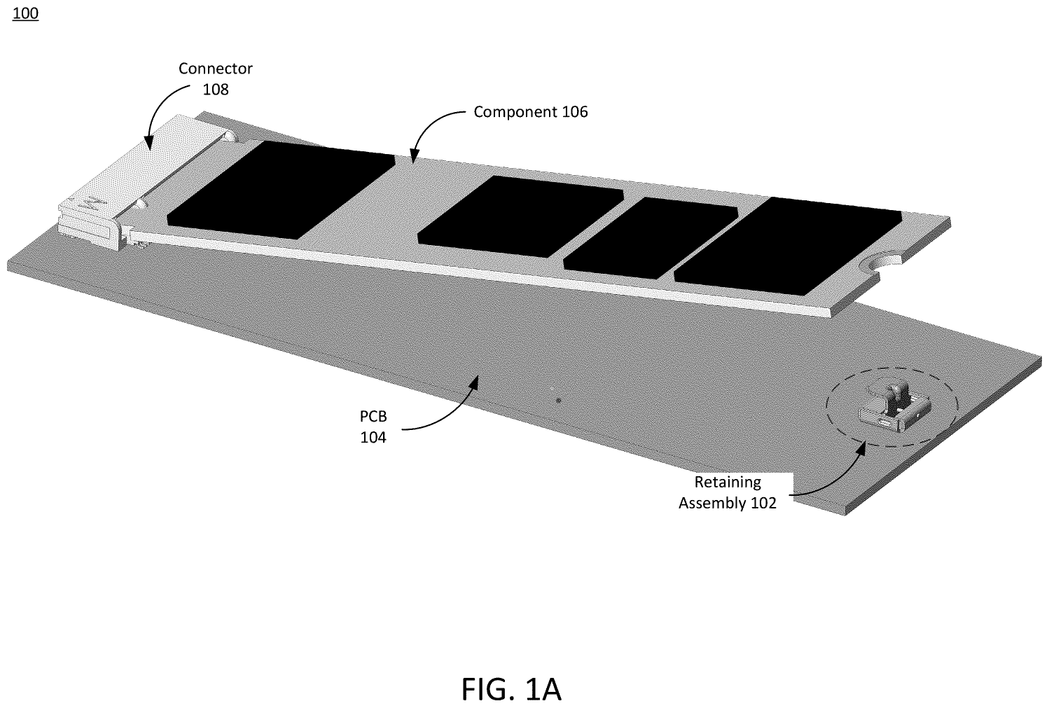

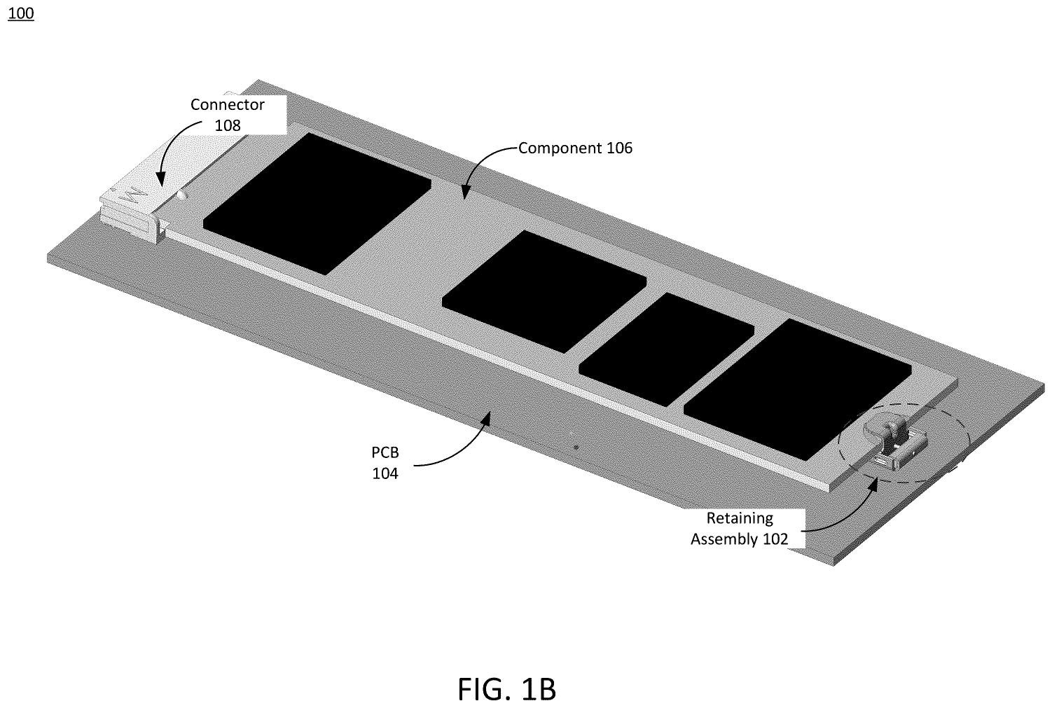

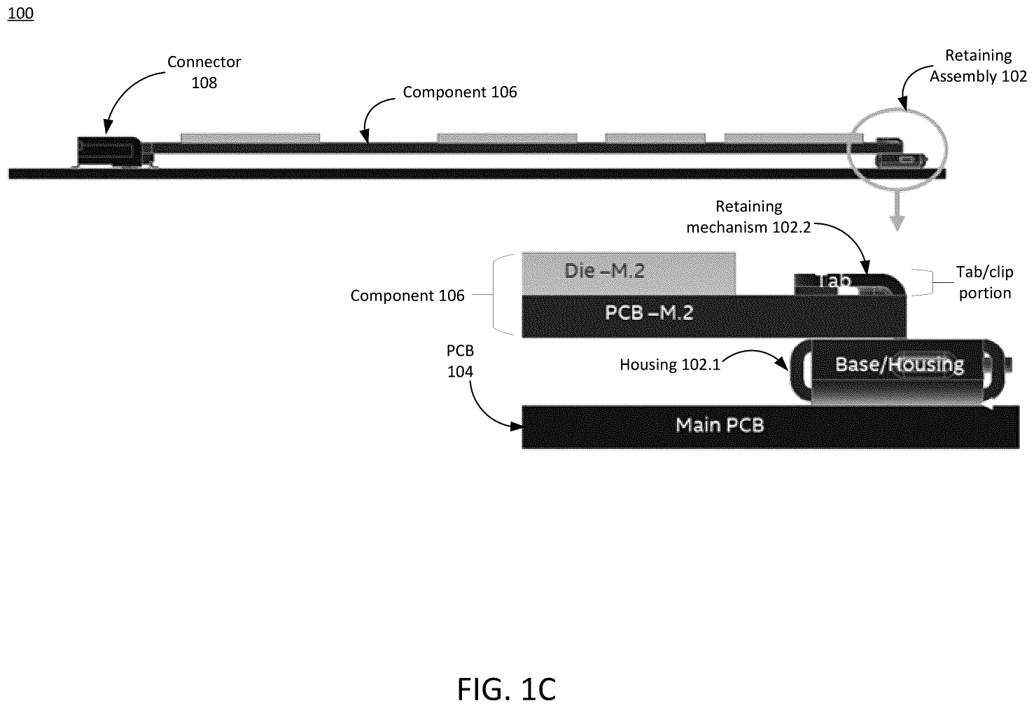

FIGS. 1A-1C illustrate various views of an electronic component installation implementing a retaining assembly, in accordance with the disclosure. As shown in FIGS. 1A-1C, the installation 100 comprises a PCB 104 to which retaining assembly 102 and a connector 108 are coupled. The retaining assembly 102 and the connector 108 may be bonded to the PCB 104 via a soldered connection or any suitable type of coupling, including known types. The PCB 104 may be identified with any suitable type of board that is implemented via any suitable type of electronic device. To provide various non-liming and illustrative scenarios, the PCB 104 may be identified with a motherboard of other suitable electronic board associated with an electronic device comprising a wireless device, a user equipment (UE), a mobile phone, a laptop computer, a tablet, a desktop computer, a wearable device, etc.

The installation 100 also comprises an electronic component 106, which has a mating connector (not shown) configured to mate with the connector 108. The electronic component 106 may comprise any suitable type of component that may be mechanically retained to the PCB via the connector 108 and the retaining assembly 102, as discussed in further detail herein. To provide various non-liming and illustrative scenarios, the electronic component 106 may comprise any suitable type of expansion card of any suitable size, such as a Peripheral Component Interconnect Express (PCIe) card, an M.2 module, etc. Such electronic components may comprise, in various non-limiting and illustrative scenarios, solid state drives (SSD), random access memory (RAM) expansion cards, graphics expansion cards, wireless local-area network (WLAN) expansion cards, Wireless wide area network (WWAN) expansion cards, etc.

However, it may be particularly advantageous for the electronic component to comprise an expansion card that adheres to the M.2 form factor specification, which implement an edge connector (e.g. the connector 108) on one side and a semicircular mounting hole at the center of the opposite edge. This is because the connector 108, when implemented as an edge connector for an M.2 module, provides a spring-biased force in a direction that is normal to the PCB 104 to help secure the electronic component 106 once retained via retaining assembly 102 via spring tension in the connector 108. Thus, when implemented as an M.2 module, the electronic component 106 is first inserted into the connector 108 as shown in FIG. 1A. Then, force is applied to the electronic component 106 towards the PCB 104. As part of this process, the semicircular mounting hole of the electronic component 106 initially displaces a retaining mechanism 102.2 of the retaining assembly 102. The retaining mechanism 102.2 then snaps back and over the PCB of the electronic component 106 due to a spring biasing force to ensure that the electronic component 106 is retained to the PCB 104, as shown in FIGS. 1B and 1C.

This is illustrated in further detail in FIG. 1C, which represents a side view of the installation 100 as shown in FIG. 1B. As shown in FIG. 1C, the retaining assembly 102 comprises a retaining mechanism 102.2 that includes an upper portion that engages with the PCB of the electronic component 106, which may be referred top herein as a tab or clip. As discussed in further detail below, the retaining mechanism 102.2 may be temporarily displaced in a direction that is opposite to the connector 108 while the electronic component 106 is pushed toward the PCB 104. As the electronic component 106 is pushed further, the semicircular mounting hole of the electronic component “clears the tab of the retaining mechanism 102.2, causing the retaining mechanism 102.2 to returns to the position as shown in FIG. 1C. Thus, in this position the retaining mechanism 102.2 acts as a clip to retain the electronic component 106 as shown, with the retaining mechanism 102.2 being configured to accept the entire thickness of the PCB of the electronic component 106 between the top of the housing 102.1 and the bottom of the tab/clip portion of the retaining mechanism 102.2. The disclosure is directed primarily to the retaining assembly 102, and thus additional details regarding its implementation and operation are discussed in further detail below.

### III. Assembly Process for a Retaining Assembly

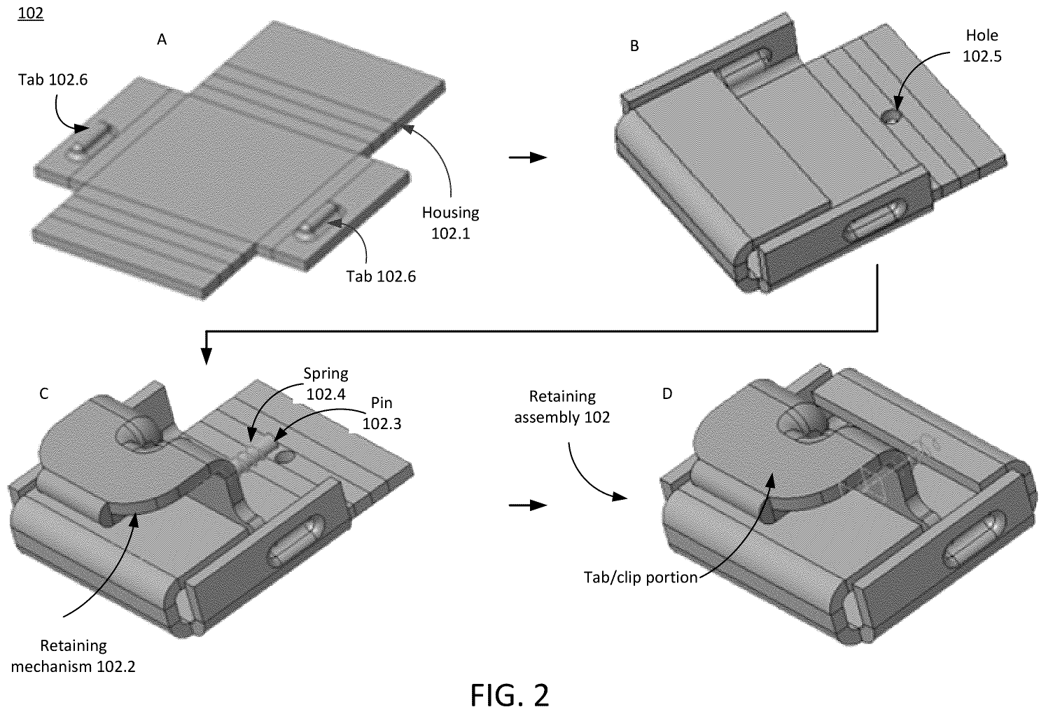

FIG. 2 illustrates a manufacturing procedure for a retaining assembly, in accordance with the disclosure. The retaining assembly 102 as shown in FIG. 2 comprises a housing 102.1, a retaining mechanism 102.2, a pin 102.3, and a spring 102.4. The housing 102.1 may be formed of a single sheet of any suitable conductive material, such as sheet metal, which may be punched out, stamped, trimmed, etc. to the desired shape for manufacturing. In various non-limiting and illustrative scenarios, the housing 102.1, the retaining mechanism 102.2, the pin 102.3, and the spring 102.4 may comprise stainless steel, brass, copper, etc., or other suitable materials that may be discussed in further detail herein. The housing 102.1, the retaining mechanism 102.2, the pin 102.3, and the spring 102.4 may comprise the same type of material or different materials, such as those discussed herein. To provide an illustrative and non-limiting scenario, the housing 102.1 may alternatively comprise other materials such as polymers, although a metal composition may be particularly useful for durability and soldering to a PCB. The housing 102.1 may be plated on one or more sides when implemented as a non-metallic material for soldering purposes. Alternatively, the housing 102.1 may be affixed to the PCB using adhesives or other suitable bonding techniques, including known techniques.

In any event, the housing 102.1 may be of any suitable size and/or shape and include tabs 102.6, which are configured to engage with corresponding notches in the retaining mechanism 102.2, as discussed in further detail below. The housing 102.1 may be folded as part of the assembly process of the retaining assembly 102, as shown by the transition from A to B in FIG. 2 in which three of the four sides are folded upwards. The fourth side of the housing 102.1 remains open for the next assembly process. As shown in FIG. 2, a hole 102.5 may bored, drilled, punched, etc. into the housing 102.1, which may be of a slightly larger diameter than the pin 102.3 such that the pin 102.3 may be disposed through the hole 102.5, as discussed in further detail below.

In process C as shown in FIG. 2, the retaining mechanism 102.2 is inserted into the housing 102.1. The spring 102.4 is inserted over the pin 102.3, and the pin 102.3 and the spring 102.4 are then inserted through a hole in the retaining mechanism 102.2. The spring 102.4 has an outer diameter slightly larger than the hole in the retaining mechanism 102.2, whereas the pin 102.3 has a diameter slightly smaller than the hole in the retaining mechanism 102.2. In this way, the pin 102.3 functions as a guide pin and may freely pass through the hole in the retaining mechanism 102.2. As a result, the retaining mechanism 102.2 is movable within the housing 102.1, as discussed in further detail herein.

In the final process D, the last edge of the housing 102.1 is folded upwards such that the pin 102.3 is aligned with the hole 102.5. Again, the diameter of the hole 102.5 may be slightly larger than the diameter of the pin 102.3 such that the pin 102.3 may pass through the hole 102.5. The pin 102.3 may then be affixed to the last folded edge of the housing 102.1 via any suitable techniques such as soldering, welding, adhesives, etc. Thus, for the process D, the pin 102.3 may be secured to the housing 102.1 and be substantially flush with the outer wall of the housing 102.1, as discussed in further detail below. Thus, the process D as shown in FIG. 2 yields the retaining assembly 102 as discussed herein.

### IV. Configuration of a Retaining Assembly

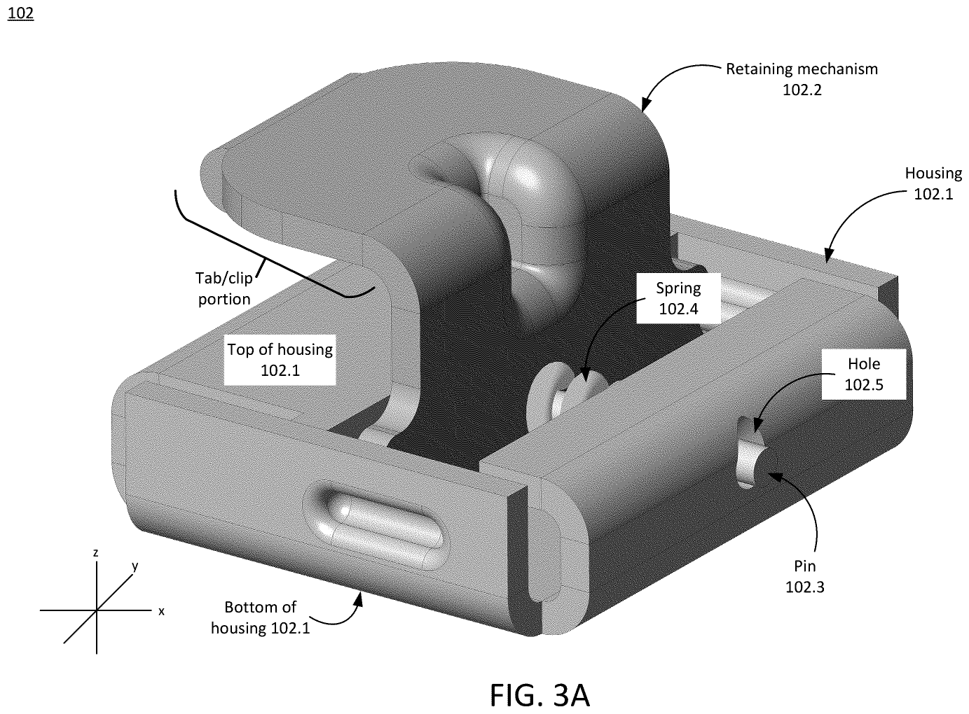

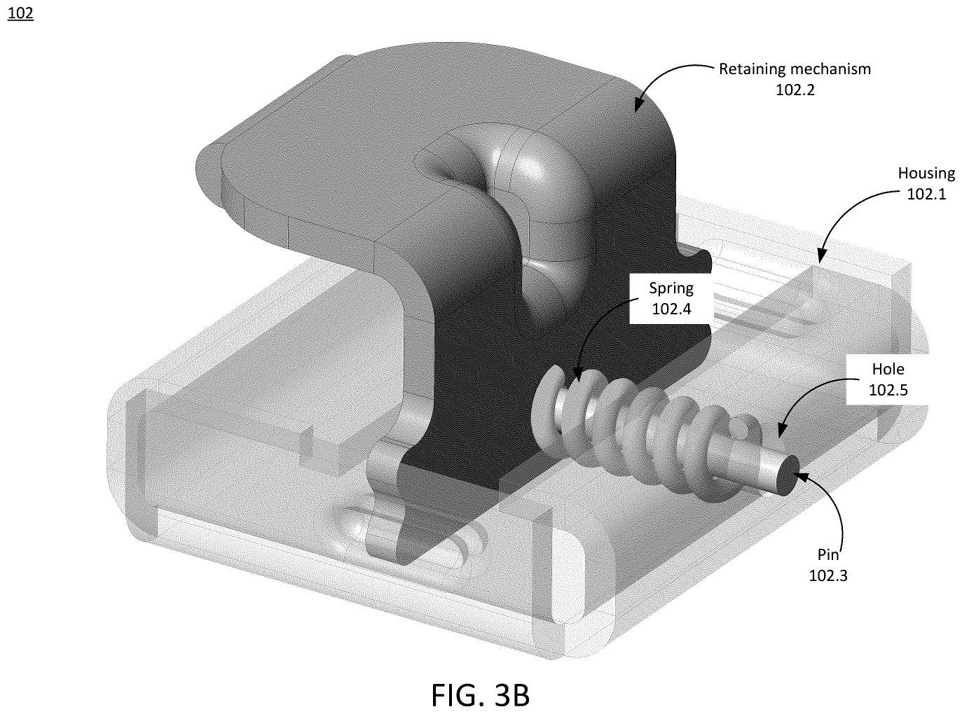

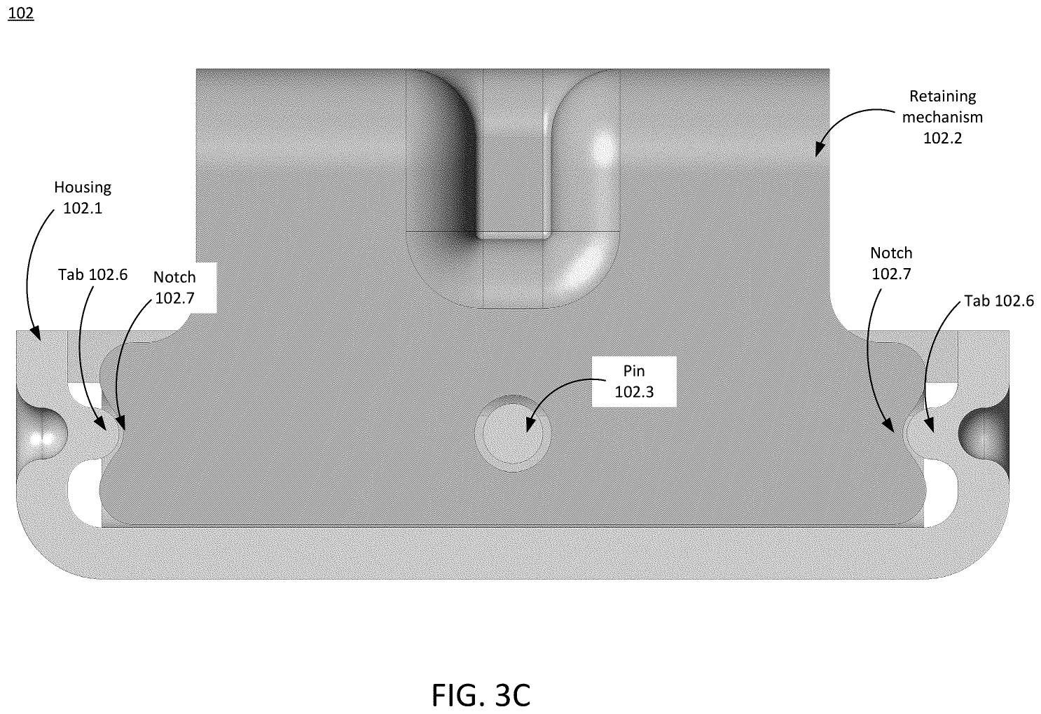

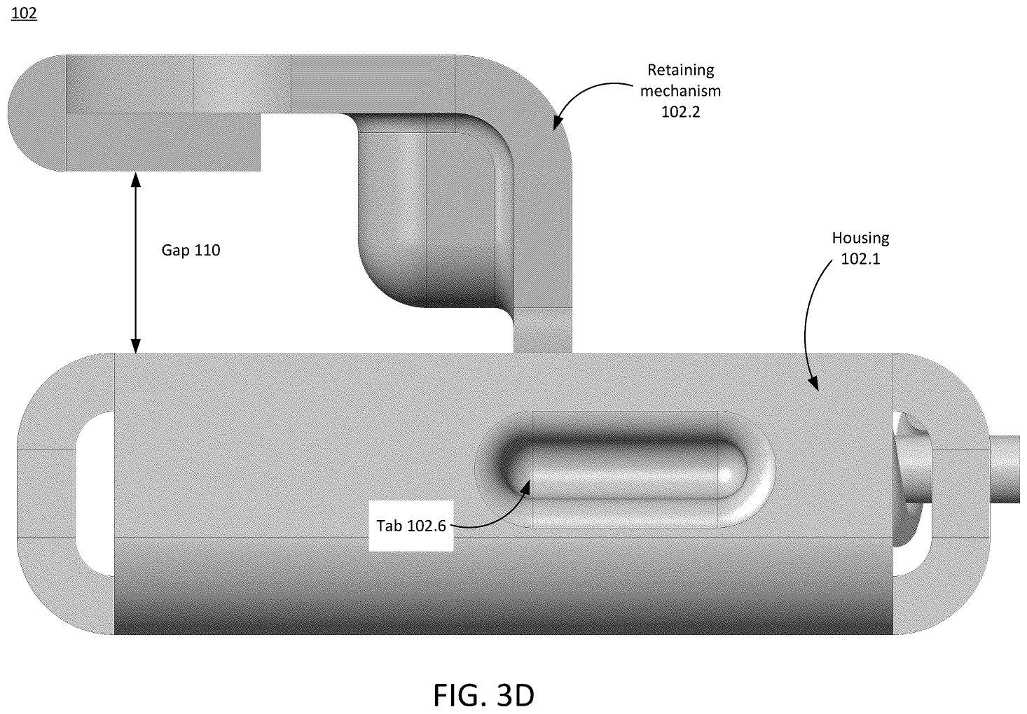

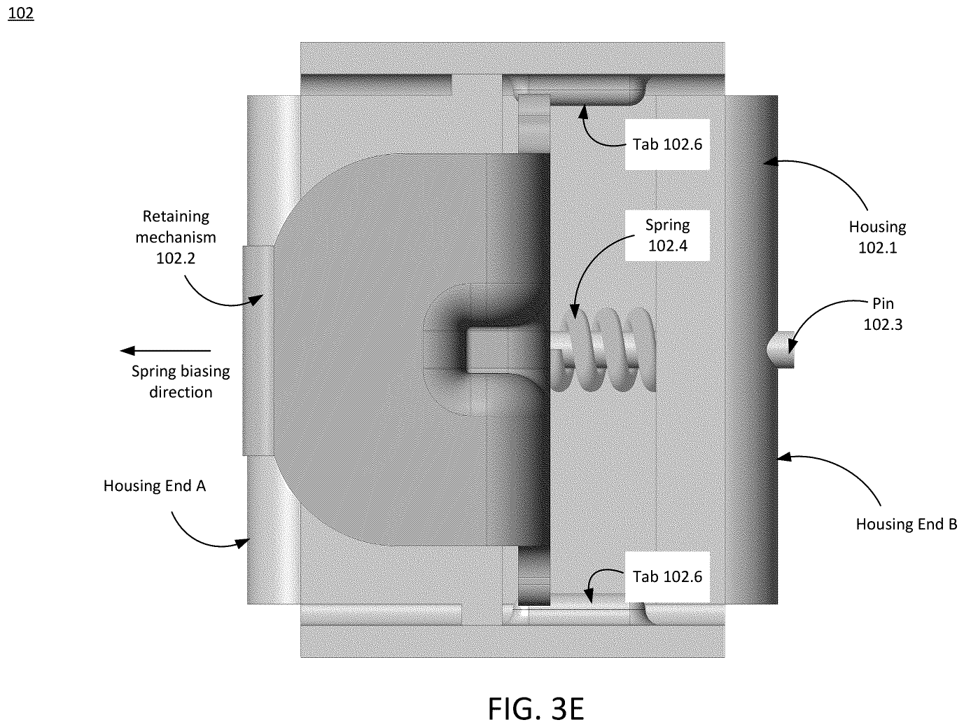

FIGS. 3A-3E illustrate various views of the retaining assembly 102. FIG. 3A illustrates a view of the retaining assembly 102 showing the pin 102.3 through the hole 102.5 prior to the pin 102.3 being bonded to the housing 102.1 as discussed above. FIG. 3B shows the same view as FIG. 3A with the housing 102.1 made transparent for ease of explanation. FIG. 3C illustrates a rear view of the retaining assembly 102 showing a cross-section of the retaining assembly 102 that is perpendicular with the axis of the pin 102.3. FIG. 3D illustrates a side view of the retaining assembly 102. FIG. 3E illustrates a top view of the retaining assembly 102.

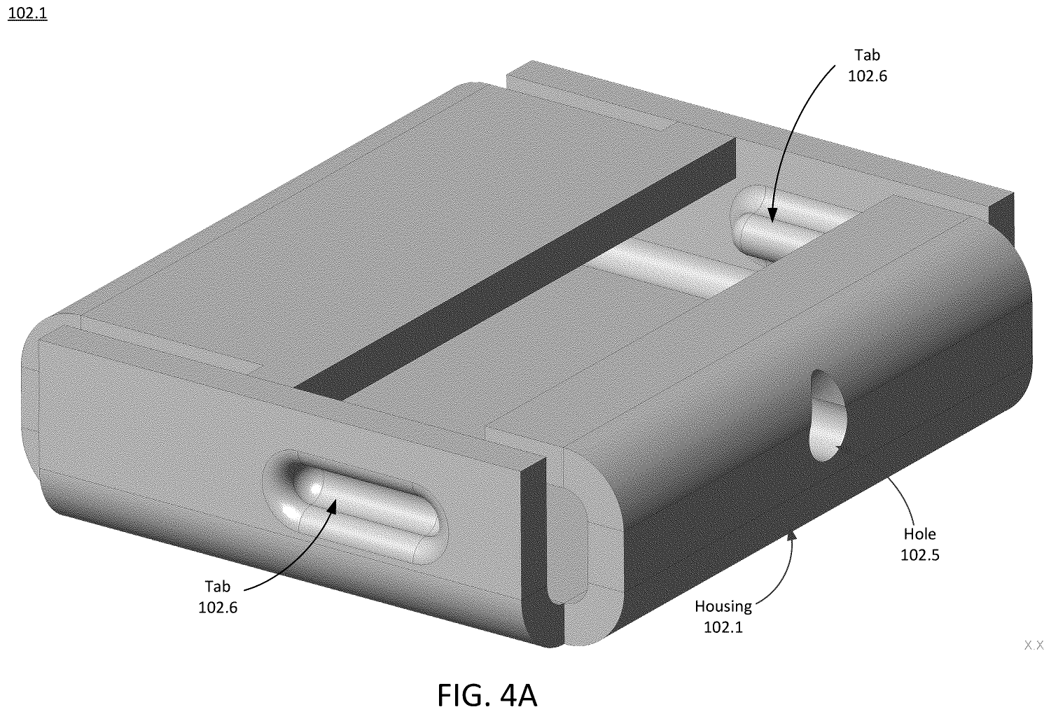

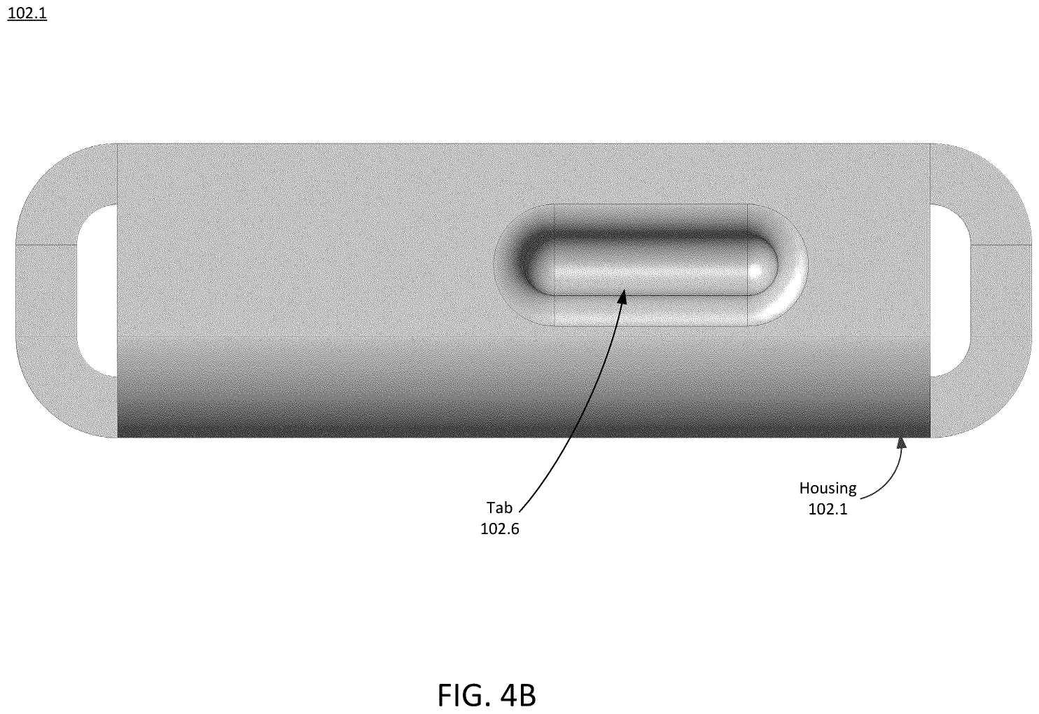

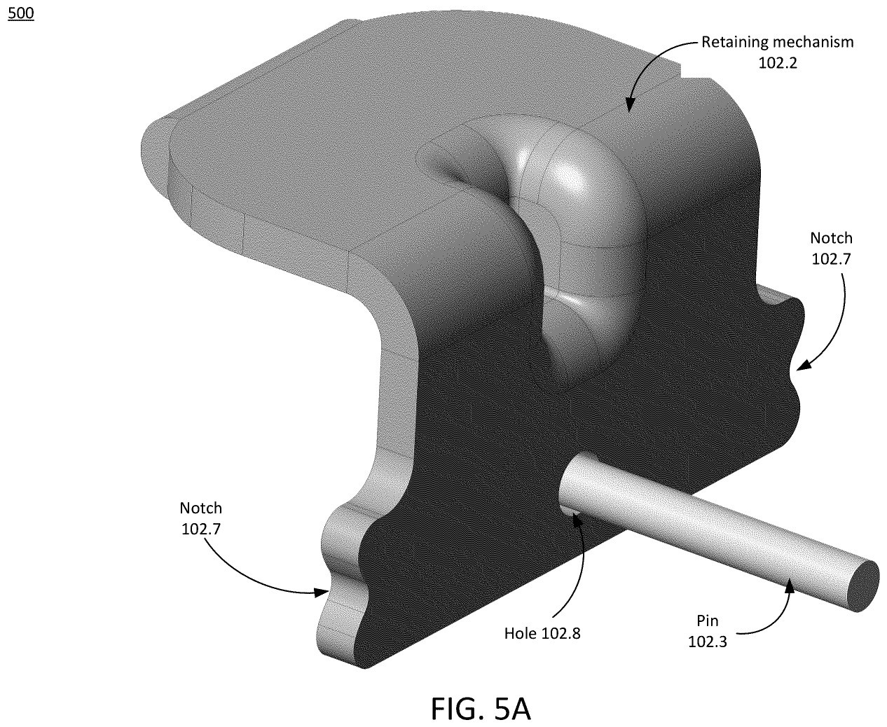

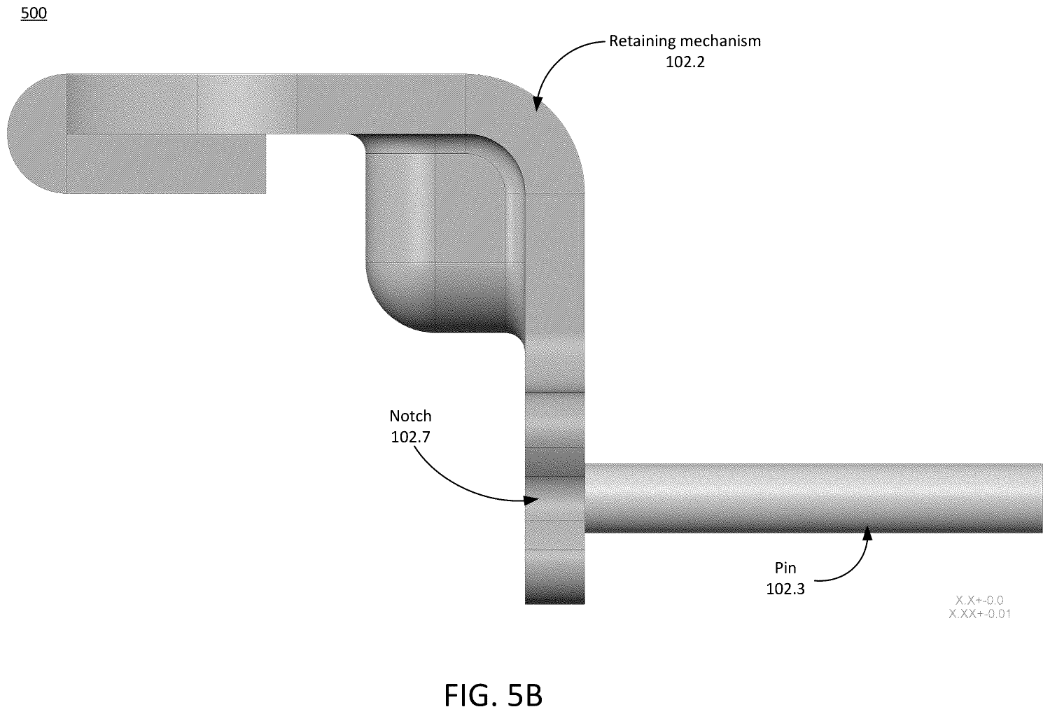

FIGS. 4A-4B illustrate various views of the housing 102.1. FIG. 4A illustrates an isometric view of the housing 102.1, whereas FIG. 4B illustrates a side view of the housing 102.1. Additionally, FIGS. 5A-5B illustrate various views of the retaining mechanism 102.2 and the pin 102.3. FIG. 5A illustrates an isometric view of the retaining mechanism 102.2 and the pin 102.3, whereas FIG. 5B illustrates a side view of the retaining mechanism 102.2 and the pin 102.3.

Again, the retaining assembly 102 comprises the housing 102.1, the retaining mechanism 102.2, the pin 102.3, and the spring 102.4. Upon assembly, as shown in process D of FIG. 2, the retaining mechanism 102.2 is configured to move within the housing 102.1. That is, the retaining mechanism 102.2 is slidably engaged within the housing 102.1 such that the retaining mechanism 102.2 may move linearly in a direction that is aligned with the central longitudinal axis of the in 102.4. To form this arrangement, and as shown in further detail in FIG. 3C, the retaining mechanism 102.2 comprises a set of notches 102.7, and the housing 102.1 comprises a set of tabs 102.6. The set of notches 102.7 in the retaining mechanism 102.2 and the set of tabs 102.6 in the housing 102.1 are aligned and engaged with one another. Additionally, the pin 102.3 is coupled (i.e. bonded) to the housing 102.1 but passes through a hole 102.8 in the retaining mechanism 102.2. Thus, the pin 102.3 functions as a guide pin, with the arrangement between the retaining mechanism 102.2 and the pin 102.3 being further shown in FIGS. 5A-5B. As shown in FIG. 3E, the spring 102.4 is disposed over the pin 102.3. The spring 102.4 has a slightly (such as 0.05%, 1%, 2%, 5%, etc.) larger outer diameter than the diameter of the hole 102.5 in the housing 102.1 and the hole 102.8 in the retaining mechanism 102.2, as shown in FIG. 3E.

As a result of this arrangement, the retaining mechanism 102.2 is spring biased towards the connector 108, e.g. towards the end A of the housing 102.1 as shown in FIG. 3E. The retaining mechanism 102.2 may be moved in a direction that is aligned with a central longitudinal axis of the pin 102.3, compressing the spring 102.4 when the retaining mechanism 102.2 is moved towards the end B of the housing 102.1, which is opposite to the end A of the housing 102.1 as shown in FIG. 3E. Thus, the engagement between the set of notches 102.7 in the retaining mechanism 102.2 and the set of tabs 102.6 in the housing 102.1 may define a portion or the entirety of the range of movement of the retaining mechanism 102.2 within the housing 102.1. In other words, and referencing the coordinate system as shown in FIG. 3A, the engagement between the set of notches 102.7 in the retaining mechanism 102.2 and the set of tabs 102.6 in the housing 102.1 (as well the pin 102.3 being disposed through the hole 102.8 in the retaining mechanism 102.2) prevents the retaining mechanism 102.2 from moving in the z-axis. In this way, the movement of the retaining assembly 102 is substantially confined within the x-y plane, and more specifically in a linear direction that is substantially parallel with the spring biasing direction as shown in FIG. 3E.

Again, the retaining mechanism 102.2 is slidably engaged within the housing 102.1. Due to this arrangement, when coupled to the PCB 104, the retaining mechanism 102.2 receives a portion of the electronic component 106 by moving the retaining mechanism 102.2 towards the end B of the housing 102.1, as shown in FIG. 3E, thereby compressing the spring 102.4. The retaining mechanism 102.2 may be moved in this manner by way of a user pushing the electronic component 106 (while connected to the connector 108) towards the PCB 104, as discussed above. That is, and using an M.2 module as a non-limiting and illustrative scenario, while the electronic component 106 is being pushed downwards towards the PCB 104, the semicircular mounting hole may displace the retaining mechanism 102.2 in a direction opposite to the biasing direction of the spring 102.4. As the electronic component 106 is pushed further towards the PCB 104, the PCB of the electronic component 106 is received into the gap 110 that is formed between the clip/tab portion of the retaining mechanism 102.2 and the housing 102.1, as shown in FIG. 3D. At this point, the retaining mechanism 102.2 moves back towards the end A of the housing 102.1, as shown in FIG. 3E, partially decompressing the spring 102.4. That is, upon the electronic component 106 being received into the gap 110, the retaining assembly 102 retains the electronic component 106 via a spring biasing of the retaining mechanism 102.2 toward the end A of the housing 102.1 by way of the force of the spring 102.4.

To ensure adequate mechanical retainment of the electronic component 106, the spring 102.4 may comprise any suitable type of spring that may generate a spring-biasing force based upon the particular application. As one non-limiting and illustrative scenario, the spring 102.4 may comprise a music wire ASTM A228 material, have a wire diameter of 0.225 mm, a spring outer diameter of 0.85 mm, a free length of 2.0 mm, 3 active coils, a spring constant of 34.66 N/mm, and generate a load of 5.631 N. When the spring 102.4 comprises these physical parameters, the spring 102.4 may retain the electronic component 106 in the presence of an upward (e.g. a z-axis) force of up to 5N. It is noted that the contact retention force of an M.2 connector (e.g. the connector 108) is typically less than 1N, meaning the spring 102.4 is 5 times stronger than its load.

In this way, the retaining mechanism 102.2 retracts when the electronic component 106 is pressed down and then latches back to its original position to retain the electronic component 106. To remove the electronic component 106, a user may then push the retaining mechanism 102.2 in the opposite direction, i.e. towards the end B of the housing 102.1 to once again compress the spring 102.4 and release the electronic component 106. Again, the connector 108 has an integrated spring mechanism that assists in pivoting the electronic component 106 to a 45° angle when the retaining mechanism 102.2 is pulled back in this manner. The 45° pivoting of the spring internal to the connector 108 provides an upward force of <1N, while the spring 102.4 may handle >5N of load. Thus, the electronic component 106 installation is performed simply by pushing in the electronic component 106 until the clip/tab of the retaining mechanism 102.2 locks the electronic component 106 into place, and the electronic component 106 is ejected by pushing the retaining mechanism 102.2 towards the edge B of the housing 102.1. This reduced effort for installation decreases the probability of the retaining assembly 102 being knocked off the PCB 104 due to the elimination of the screw and the need to provide any torque to the retaining assembly 102.

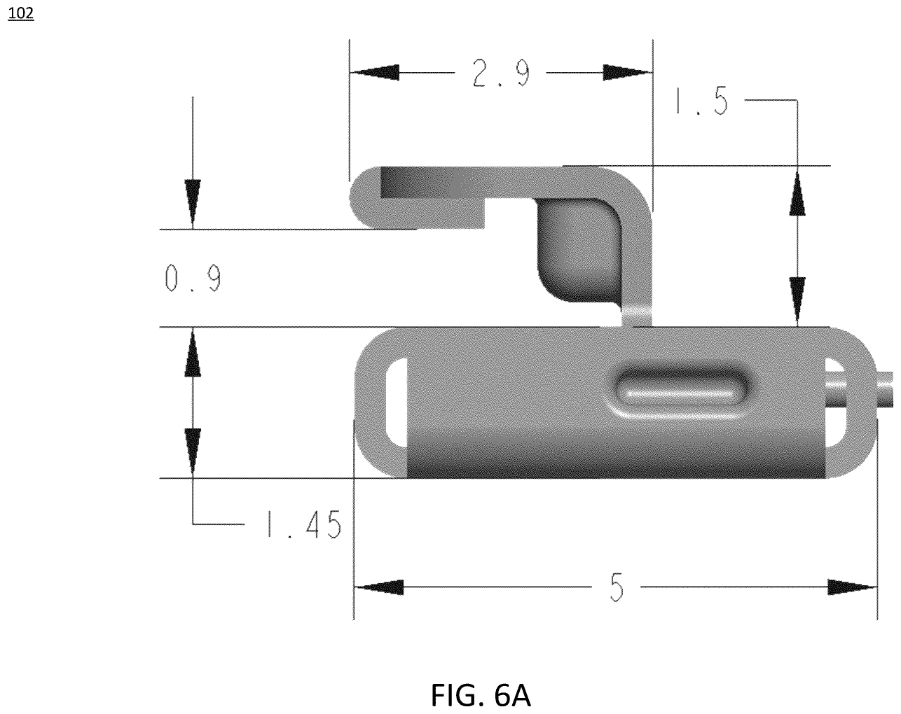

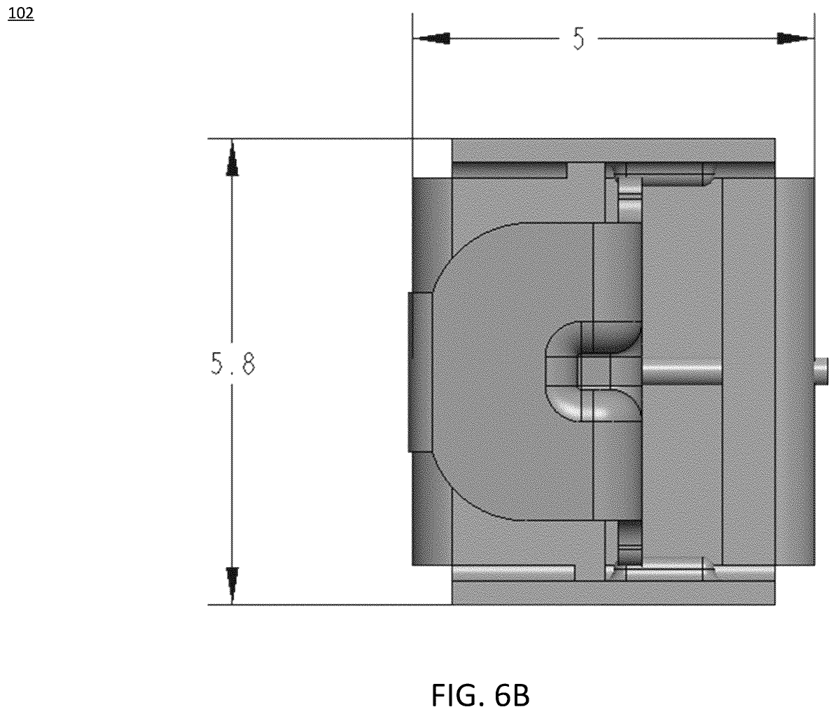

The retaining assembly 102 may have any suitable size to ensure that a corresponding electronic component 106 is adequately retained. To this end, FIGS. 6A and 6B illustrate sample dimensions of a retaining assembly, in accordance with the disclosure. FIG. 6A illustrates a side view of the retaining assembly 102 showing sample dimensions, whereas FIG. 6B illustrates a top view of the retaining assembly 102 showing sample dimensions. These dimensions are provided as a non-limiting and illustrative scenario, as the retaining assembly 102 may have alternate dimensions based upon the particular application.

As shown in FIGS. 6A and 6B, the housing 102.1 may have a width of 5.0 mm, a length of 5.8 mm, and a height of 1.45 mm. The gap 110 as shown and discussed with respect to FIG. 3D is shown in FIG. 6A as 0.9 mm, and it is noted that a typical M.2 module has a PCB thickness of 0.8 mm. The retaining mechanism 102.2 also has a tab length of 2.9 mm, which clips over the PCB of the electronic component 106 as shown in FIG. 1C. As a result, the overall height (e.g. z profile) of the retaining assembly is just under 3 mm (2.95 mm). The retaining assembly 102 is thus well suited for a low-profile system in which an SMT standoff/insert is not usable due to an insufficient thread count required to provide reliable mechanical retention, as noted above.

Again, FIG. 3E illustrates a top view of the retaining assembly 102. The bottom of the housing 102.1 is on a side of the housing 102.2 that is opposite to the top side of the retaining assembly 102, as shown in FIG. 3A. The bottom of the housing 102.1 may be bonded to the PCB 104 via solder, adhesive, etc., as discussed above. When soldered, the PCB 104 may have a corresponding PCB pad that corresponds to at least a portion of the bottom of the housing 102.1. Given the sample dimensions noted above with respect to FIGS. 6A and 6B, the PCB solder pad may have dimensions of 5 mm×4 mm, providing a soldering area of 20 mm². This soldering pad area provides sufficient bond strength to retain the retaining assembly 102 in place, as verified by structural simulations.

Specifically, structural simulations were performed to evaluate the strength of the solder and the retaining assembly 102 with a spring force of 5 N in both the vertical (e.g. the z) and the lateral (e.g. the x and y) directions. A factor of safety of ˜1.4 was observed in the solder material and a factor of safety of ˜1.6 was observed in the parts of the retaining assembly 102. Moreover, a structural simulation was performed to evaluate the retaining assembly 102 for a shock (e.g. drop) test and a vibration test under various conditions. A minimum factor of safety of 1.2 was observed in the solder material and factor of safety of ˜1.8 was observed for the parts of the retaining assembly 102.

### V. Advantages Over Conventional Mechanical Retention Systems

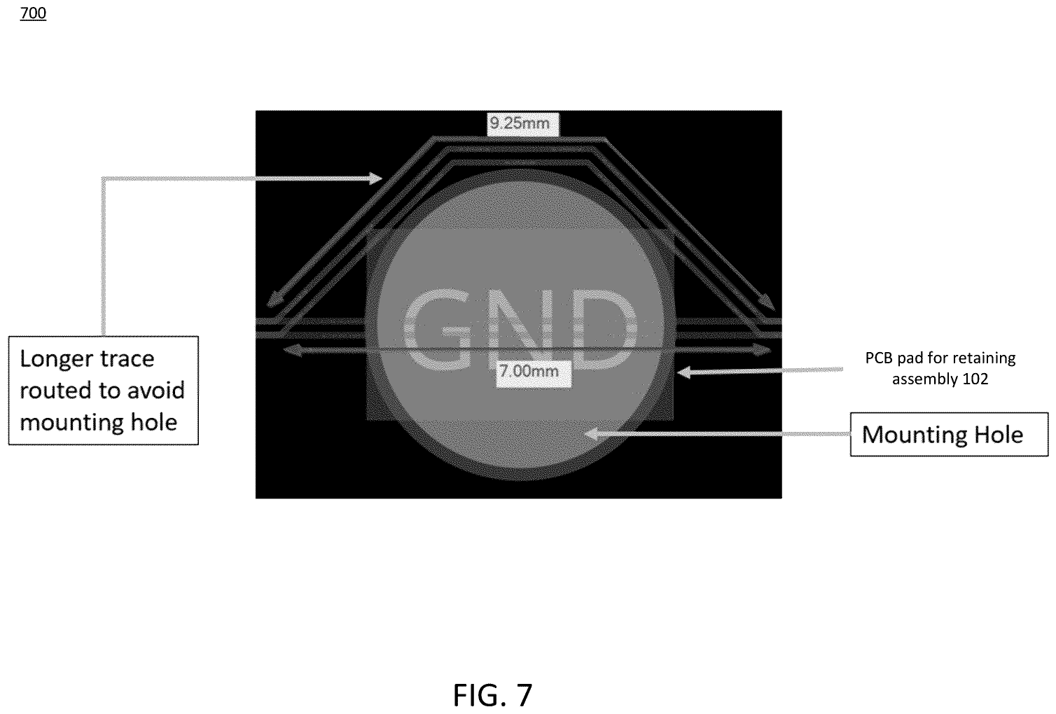

FIG. 7 illustrates the use of a PCB solder pad for the retaining assembly compared to conventional PCB mounting holes, in accordance with the disclosure. As shown in FIG. 7, the SMT clip pad is assumed to be 5.0 mm×4.0 mm, as discussed above. Although the PCB solder pad may have any suitable dimensions, it may be particularly advantageous to implement a smaller PCB area. Thus, as one non-limiting and illustrative scenario, the retaining assembly 102 may be soldered to the PCB 104 using a maximum PCB pad area of 5.0 mm×4.0 mm (i.e. 20 mm²), as shown in FIG. 7. In other words, the retaining assembly 102 may be soldered to the PCB 104 via the housing 102.1 using a PCB pad area less than or equal to about (e.g. within. 0.1%, 1%, 0.5%, 5%, 10%, etc.) 20 mm².

Advantageously, the use of the retaining assembly 102 increases the usable routing area in the inner layers of the board by 20 mm² on each routing layer per retaining assembly 102 that is implemented, as through holes are not required on the PCB. For instance, and as shown in FIG. 7, a conventional through hole standoff requires a footprint diameter of 5.7 mm and, due to design for manufacturing (DFM) rules, the inner layer traces are required to be at least 0.225 mm away from the drilled hole to prevent damage to internal traces.

Thus, the use of the retaining assembly 102 improves the assembly yield for manufacturing while reducing the requirement for screws in the BOM. The use of the retaining assembly 102 also provides more routing area on all the inner layers. As an example, a mobile gaming laptop is considered with 4×SSD, 1×WLAN, and 1×WWAN on a 12 layered PCB board. For this electronic device, 6 retaining assemblies 102 would be used (i.e. one per electronic component). This saves a total of 1200 mm² of PCB area available for signal routing and/or the power/ground plane.

Besides providing more area for PCB routing, implementing the retaining assembly 102 also helps to reduce the trace length by 2.25 mm (for any traces that pass through in the inner layer underneath the retaining assembly 102 in comparison to the mounting hole) as shown in FIG. 7. This also improves signal integrity and avoids length mismatches for any high-speed differential pairs that run under the PCB solder pad of the retaining assembly 102.

Additionally, it is noted that the retaining assembly 102 provides a solution that yields ease of assembly and servicing due to its screwless design. No tools are needed for assembly or dis-assembly, providing ease of assembly and removal of the electronic component 106. Additionally, the time needed for installation is reduced, and eliminating the use of a screw further reduces the parts needed for a mechanical bill of materials (BOM).

### VI. An Electronic Device

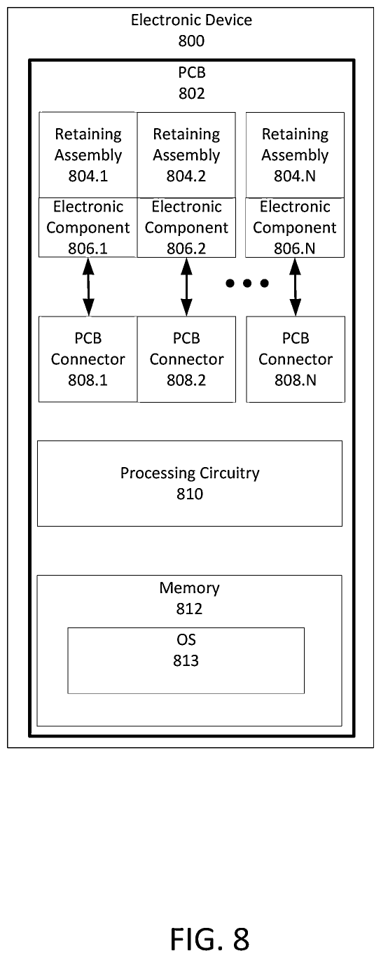

FIG. 8 illustrates an electronic device, in accordance with the present disclosure. The electronic device 800 may be identified with any suitable type of device that implements any suitable number of the retaining assembly 102 as discussed herein to retain a corresponding electronic component 106. The electronic device 800 may be identified with any suitable device that utilizes the retaining assembly 102 to retain any suitable type of electronic components, which may comprise expansion cards and/or M.2 modules as discussed herein. Thus, the electronic device 800 may be identified with a wireless device, a user equipment (UE), a mobile phone, a laptop computer, a tablet, a wearable device, etc.

The electronic device 800 may comprise a PCB 802, which may have any suitable number of layers. The PCB 802 may be identified, in a non-limiting and illustrative scenario, with the PCB 104 as discussed herein. The electronic device 800 may further comprise any suitable number of retaining assemblies 804.1-804.N, each being coupled to the PCB 802 via a corresponding PCB solder pad on the PCB 802 as part of a surface mount soldering process, as discussed herein.

The electronic device 800 may comprise, for each of the retaining assemblies 804.1-804.N, a corresponding electronic component 806.1-806.N, each having a respective connector 808.1-808. N. Each of the retaining assemblies 804.1-804.N may be identified, in a non-limiting and illustrative scenario, with the retaining assembly 102 as discussed herein. Each of the electronic components 806.1-806.N may be identified, in a non-limiting and illustrative scenario, with the electronic component 106 as discussed herein, which again may comprise an M.2 module or other suitable type of internal expansion card. Each of the connectors 808.1-808.N may be identified, in a non-limiting and illustrative scenario, with the connector 108 as discussed herein.

The electronics device 800 may comprise processing circuitry 810, which may be configured as any suitable number and/or type of computer processors, and which may function to control the electronic device 800 and/or other components of the electronic device 800. The processing circuitry 810 may be identified with one or more processors (or suitable portions thereof) implemented by the electronic device 800. The processing circuitry 810 may be identified with one or more processors such as a host processor, a digital signal processor, one or more microprocessors, graphics processors, baseband processors, microcontrollers, an application-specific integrated circuit (ASIC), part (or the entirety of) a field-programmable gate array (FPGA), etc.

In any event, the processing circuitry 810 may be configured to carry out instructions to perform arithmetical, logical, and/or input/output (I/O) operations, and/or to control the operation of one or more components of electronic device 800 to perform various functions as described herein. The processing circuitry 810 may include one or more microprocessor cores, memory registers, buffers, clocks, etc., and may generate electronic control signals associated with the components of the electronic device 800 to control and/or modify the operation of these components. The processing circuitry 814 may communicate with and/or control functions associated with the memory 812, as well as any other components of the electronic device 800.

The memory 812 stores data and/or instructions such that, when executed by the processing circuitry 810, cause the electronic device 800 to perform various functions such as controlling, monitoring, and/or regulating the operation of the electronic device 800, providing data to be transmitted and/or received between the components 604, 612, processing signals that are received via the electronic components 806.1-806.N, etc. The memory 812 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc. The memory 812 may be non-removable, removable, or a combination of both. The memory 812 may be implemented as a non-transitory computer readable medium storing one or more executable instructions such as, for example, logic, algorithms, code, etc. The instructions, logic, code, etc., stored in the memory 812 are represented by the (operating system) OS module 813 as shown, which may enable the functionality of the electronic device 800 to be functionally realized.

### VII. A Process Flow

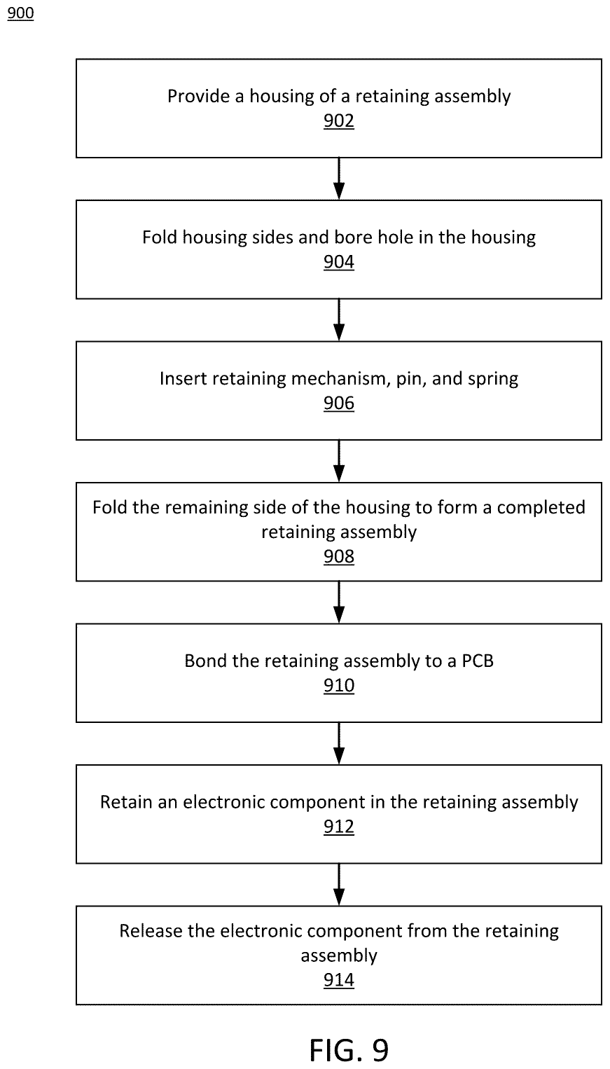

FIG. 9 illustrates a process flow, in accordance with the present disclosure. With reference to FIG. 9, the flow 900 may be a manual process, a fully-automated process, or a partially-automated process. When fully or partially automated, any portion or the entirety of the flow 900 may be implemented as a computer-implemented process executed by and/or otherwise associated with one or more processors. These processors may be associated with one or more computing components identified with any suitable computing device, such as a computing device or manufacturing component configured to perform such functionality. The one or more processors identified with one or more of the computing components as discussed herein may execute instructions stored on any suitable computer-readable storage medium. The flow 900 may include alternate or additional steps that are not shown in FIG. 9 for purposes of brevity, and may be performed in a different order than the steps shown in FIG. 9.

Flow 900 may begin by providing (block 902) a housing of a retaining assembly. This may include providing a single sheet of any suitable conductive material, which may be stamped, punched out, or otherwise trimmed to the desired shape, as discussed above with respect to the process A in FIG. 2 for the housing 102.1.

The flow 900 may further comprise folding (block 904) sides of the housing and boring a hole in the housing. This may include folding three sides of the single sheet of material that was previously provided (block 902), and forming a hole in a portion of the housing to accept the pin 102.3, as discussed above with respect to the process B in FIG. 2.

The flow 900 may further comprise inserting (block 906) a retaining mechanism, pin, and spring into the folded housing. This may include inserting the retaining mechanism 102.2, pin 102.3, and spring 102.4 into the housing 102.1 as discussed above with respect to the process C in FIG. 2. This may also include disposing the spring 102.4 over the pin 102.3, which is disposed through the hole 102.8 in the retaining mechanism 102.2.

The flow 900 may further comprise folding (block 908) the remaining side of the housing to form a completed retaining assembly. This may include disposing the pin 102.3 through the hole 102.5 in the housing 102.1, as discussed above with respect to the process D in FIG. 2. This may also include bonding the pin 102.3 to the hole 102.5 in the last folded edge of the housing 102.1 via soldering, welding, etc., as discussed herein.

The flow 900 may further comprise bonding (block 910) the retaining assembly to a PCB. This may include soldering, welding, or otherwise fixing the retaining assembly 102 to a PCB, such as the PCB 104 as discussed herein. The bonding of the retaining assembly to the PCB may include soldering the retaining assembly 102 to a solder pad on the PCB, as discussed herein. This may include an action that is performed as part of a manufacturing process such as a pick-and-place machine for a PCB, such as the PCB 104.

The flow 900 may further comprise retaining (block 912) an electronic component in the retaining assembly. This may include pushing the electronic component 106 into the retaining assembly 102, as discussed herein and as shown in FIGS. 1A-1C.

The flow 900 may further comprise releasing (block 914) an electronic component from the retaining assembly. This may include pushing the retaining mechanism 102.2 towards the end B of the housing 102.1 to recompress the spring 102.4, as discussed herein. The electronic component may then be removed from the electronic device.

### VIII. General Configuration of a First Retaining Assembly

A retaining assembly is provided. The retaining assembly comprises a housing and a retaining mechanism movable within the housing. The retaining mechanism is movable towards a first end of the housing to (i) receive a portion of an electronic component, and (ii) retain the electronic component via a biasing of the retaining mechanism toward a second end of the housing. In addition or in alternative to and in any combination with the optional features previously explained in this paragraph, the retaining assembly is a surface-mounted retaining assembly. In addition or in alternative to and in any combination with the optional features previously explained in this paragraph, the housing is configured to be soldered to a printed circuit board (PCB) pad having an area less than about 20 mm². In addition or in alternative to and in any combination with the optional features previously explained in this paragraph, the electronic component comprises an M.2 module. In addition or in alternative to and in any combination with the optional features previously explained in this paragraph, the first end of the housing is opposite to the second end of the housing. In addition or in alternative to and in any combination with the optional features previously explained in this paragraph, the retaining assembly further comprises a pin coupled to the first end of the housing and disposed through a hole in the retaining mechanism, and a spring disposed over the pin and compressed when the retaining mechanism is moved towards the first end of the housing. In addition or in alternative to and in any combination with the optional features previously explained in this paragraph, the retaining mechanism is movable in a direction that is aligned with a center longitudinal axis of the pin. In addition or in alternative to and in any combination with the optional features previously explained in this paragraph, the retaining mechanism comprises a set of notches, and a set of tabs of the housing engage with the notches in the retaining mechanism. In addition or in alternative to and in any combination with the optional features previously explained in this paragraph, a region in which the set of tabs of the housing and the set of notches of the retaining mechanism engage with one another defines at least a portion of a range of movement of the retaining mechanism within the housing.

### IX. General Configuration of an Electronic Device

An electronic device is provided. The electronic device comprises a printed circuit board (PCB) and a retaining assembly. The retaining assembly comprises a housing and a retaining mechanism movable within the housing. The retaining assembly is movable towards a first end of the housing to (i) receive a portion of an electronic component, and (ii) retain the electronic component via a biasing of the retaining mechanism toward a second end of the housing. In addition or in alternative to and in any combination with the optional features previously explained in this paragraph, the retaining assembly is a surface-mounted retaining assembly. In addition or in alternative to and in any combination with the optional features previously explained in this paragraph, the housing is configured to be soldered to a printed circuit board (PCB) pad having an area less than about 20 mm². In addition or in alternative to and in any combination with the optional features previously explained in this paragraph, the electronic component comprises an M.2 module. In addition or in alternative to and in any combination with the optional features previously explained in this paragraph, the first end of the housing is opposite to the second end of the housing. In addition or in alternative to and in any combination with the optional features previously explained in this paragraph, the retaining assembly further comprises a pin coupled to the first end of the housing and disposed through a hole in the retaining mechanism, and a spring disposed over the pin and compressed when the retaining mechanism is moved towards the first end of the housing. In addition or in alternative to and in any combination with the optional features previously explained in this paragraph, the retaining mechanism is movable in a direction that is aligned with a center longitudinal axis of the pin. In addition or in alternative to and in any combination with the optional features previously explained in this paragraph, the retaining mechanism comprises a set of notches, and a set of tabs of the housing engage with the notches in the retaining mechanism. In addition or in alternative to and in any combination with the optional features previously explained in this paragraph, a region in which the set of tabs of the housing and the set of notches of the retaining mechanism engage with one another defines at least a portion of a range of movement of the retaining mechanism within the housing.

### X. General Configuration of a Second Retaining Assembly

A retaining assembly is provided. The retaining assembly comprises a housing and a retaining means for retaining an electronic component, the retaining means being movable within the housing. The retaining means is movable towards a first end of the housing to (i) receive a portion of the electronic component, and (ii) retain the electronic component via a biasing of the retaining means toward a second end of the housing. In addition or in alternative to and in any combination with the optional features previously explained in this paragraph, the retaining assembly is a surface-mounted retaining assembly, the electronic component comprises an M.2 module, and the first end of the housing is opposite to the second end of the housing.

### Examples

The following examples pertain to various techniques of the present disclosure.

An example (e.g. example 1) is directed to a retaining assembly, comprising: a housing; and a retaining mechanism movable within the housing, wherein the retaining mechanism is movable towards a first end of the housing to (i) receive a portion of an electronic component, and (ii) retain the electronic component via a biasing of the retaining mechanism toward a second end of the housing.

Another example (e.g. example 2), relates to a previously-described example (e.g. example 1), wherein the retaining assembly is a surface-mounted retaining assembly.

Another example (e.g. example 3) relates to a previously-described example (e.g. one or more of examples 1-2), wherein the housing is configured to be soldered to a printed circuit board (PCB) pad having an area less than about 20 mm².

Another example (e.g. example 4) relates to a previously-described example (e.g. one or more of examples 1-3), wherein the electronic component comprises an M.2 module.

Another example (e.g. example 5) relates to a previously-described example (e.g. one or more of examples 1-4), wherein the first end of the housing is opposite to the second end of the housing.

Another example (e.g. example 6) relates to a previously-described example (e.g. one or more of examples 1-5), further comprising: a pin coupled to the first end of the housing and disposed through a hole in the retaining mechanism; and a spring disposed over the pin and compressed when the retaining mechanism is moved towards the first end of the housing.

Another example (e.g. example 7) relates to a previously-described example (e.g. one or more of examples 1-6), wherein the retaining mechanism is movable in a direction that is aligned with a center longitudinal axis of the pin.

Another example (e.g. example 8) relates to a previously-described example (e.g. one or more of examples 1-7), wherein the retaining mechanism comprises a set of notches, and a set of tabs of the housing engage with the notches in the retaining mechanism.

Another example (e.g. example 9) relates to a previously-described example (e.g. one or more of examples 1-8), wherein a region in which the set of tabs of the housing and the set of notches of the retaining mechanism engage with one another defines at least a portion of a range of movement of the retaining mechanism within the housing.

An example (e.g. example 10) is directed to an electronic device, comprising: a printed circuit board (PCB); and a retaining assembly, comprising: a housing; and a retaining mechanism movable within the housing, wherein the retaining assembly is movable towards a first end of the housing to (i) receive a portion of an electronic component, and (ii) retain the electronic component via a biasing of the retaining mechanism toward a second end of the housing.

Another example (e.g. example 11), relates to a previously-described example (e.g. example 10), wherein the retaining assembly is a surface-mounted retaining assembly.

Another example (e.g. example 12) relates to a previously-described example (e.g. one or more of examples 10-11), wherein the housing is configured to be soldered to a printed circuit board (PCB) pad having an area less than about 20 mm².

Another example (e.g. example 13) relates to a previously-described example (e.g. one or more of examples 10-12), wherein the electronic component comprises an M.2 module.

Another example (e.g. example 14) relates to a previously-described example (e.g. one or more of examples 10-13), wherein the first end of the housing is opposite to the second end of the housing.

Another example (e.g. example 15) relates to a previously-described example (e.g. one or more of examples 10-14), wherein the retaining assembly further comprises: a pin coupled to the first end of the housing and disposed through a hole in the retaining mechanism; and a spring disposed over the pin and compressed when the retaining mechanism is moved towards the first end of the housing.

Another example (e.g. example 16) relates to a previously-described example (e.g. one or more of examples 10-15), wherein the retaining mechanism is movable in a direction that is aligned with a center longitudinal axis of the pin.

Another example (e.g. example 17) relates to a previously-described example (e.g. one or more of examples 10-16), wherein the retaining mechanism comprises a set of notches, and a set of tabs of the housing engage with the notches in the retaining mechanism.

Another example (e.g. example 18) relates to a previously-described example (e.g. one or more of examples 10-17), wherein a region in which the set of tabs of the housing and the set of notches of the retaining mechanism engage with one another defines at least a portion of a range of movement of the retaining mechanism within the housing.

An example (e.g. example 19) is directed to a retaining assembly, comprising: a housing; and a retaining means for retaining an electronic component, the retaining means being movable within the housing, wherein the retaining means is movable towards a first end of the housing to (i) receive a portion of the electronic component, and (ii) retain the electronic component via a biasing of the retaining means toward a second end of the housing.

Another example (e.g. example 20), relates to a previously-described example (e.g. example 19), wherein: the retaining assembly is a surface-mounted retaining assembly, the electronic component comprises an M.2 module, and the first end of the housing is opposite to the second end of the housing.

An example (e.g. example 21) is directed to a retaining assembly, comprising: a housing means; and a retaining means movable within the housing means, wherein the retaining means is movable towards a first end of the housing means to (i) receive a portion of an electronic component, and (ii) retain the electronic component via a biasing of the retaining means toward a second end of the housing means.

Another example (e.g. example 22), relates to a previously-described example (e.g. example 21), wherein the retaining assembly is a surface-mounted retaining assembly.

Another example (e.g. example 23) relates to a previously-described example (e.g. one or more of examples 21-22), wherein the housing means is configured to be soldered to a printed circuit board (PCB) pad having an area less than about 20 mm².

Another example (e.g. example 24) relates to a previously-described example (e.g. one or more of examples 21-23), wherein the electronic component comprises an M.2 module.

Another example (e.g. example 25) relates to a previously-described example (e.g. one or more of examples 21-24), wherein the first end of the housing means is opposite to the second end of the housing means.

Another example (e.g. example 26) relates to a previously-described example (e.g. one or more of examples 21-25), further comprising: a pin coupled to the first end of the housing means and disposed through a hole in the retaining means; and a biasing means disposed over the pin and compressed when the retaining means is moved towards the first end of the housing means.

Another example (e.g. example 27) relates to a previously-described example (e.g. one or more of examples 21-26), wherein the retaining means is movable in a direction that is aligned with a center longitudinal axis of the pin.

Another example (e.g. example 28) relates to a previously-described example (e.g. one or more of examples 21-27), wherein the retaining means comprises a set of notches, and a set of tabs of the housing means engage with the notches in the retaining means.

Another example (e.g. example 29) relates to a previously-described example (e.g. one or more of examples 21-28), wherein a region in which the set of tabs of the housing and the set of notches of the retaining means engage with one another defines at least a portion of a range of movement of the retaining means within the housing means.

An example (e.g. example 30) is directed to an electronic device, comprising: a printed circuit board (PCB); and a retaining assembly, comprising: a housing means; and a retaining means movable within the housing means, wherein the retaining assembly is movable towards a first end of the housing means to (i) receive a portion of an electronic component, and (ii) retain the electronic component via a biasing of the retaining means toward a second end of the housing means.

Another example (e.g. example 31), relates to a previously-described example (e.g. example 30), wherein the retaining assembly is a surface-mounted retaining assembly.

Another example (e.g. example 32) relates to a previously-described example (e.g. one or more of examples 30-31), wherein the housing means is configured to be soldered to a printed circuit board (PCB) pad having an area less than about 20 mm².

Another example (e.g. example 33) relates to a previously-described example (e.g. one or more of examples 30-32), wherein the electronic component comprises an M.2 module.

Another example (e.g. example 34) relates to a previously-described example (e.g. one or more of examples 30-33), wherein the first end of the housing means is opposite to the second end of the housing means.

Another example (e.g. example 35) relates to a previously-described example (e.g. one or more of examples 30-34), wherein the retaining assembly further comprises: a pin coupled to the first end of the housing and disposed through a hole in the retaining means; and a biasing means disposed over the pin and compressed when the retaining means is moved towards the first end of the housing means.

Another example (e.g. example 36) relates to a previously-described example (e.g. one or more of examples 30-35), wherein the retaining means is movable in a direction that is aligned with a center longitudinal axis of the pin.

Another example (e.g. example 37) relates to a previously-described example (e.g. one or more of examples 30-36), wherein the retaining means comprises a set of notches, and a set of tabs of the housing means engage with the notches in the retaining means.

Another example (e.g. example 38) relates to a previously-described example (e.g. one or more of examples 30-37), wherein a region in which the set of tabs of the housing means and the set of notches of the retaining means engage with one another defines at least a portion of a range of movement of the retaining means within the housing means.

An example (e.g. example 39) is directed to a retaining assembly, comprising: a housing means; and a retaining means for retaining an electronic component, the retaining means being movable within the housing means, wherein the retaining means is movable towards a first end of the housing means to (i) receive a portion of the electronic component, and (ii) retain the electronic component via a biasing of the retaining means toward a second end of the housing means.

Another example (e.g. example 40), relates to a previously-described example (e.g. example 39), wherein: the retaining assembly is a surface-mounted retaining assembly, the electronic component comprises an M.2 module, and the first end of the housing means is opposite to the second end of the housing means.

An apparatus as shown and described.

A method as shown and described.

### CONCLUSION

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

What is claimed is:

1. A retaining assembly, comprising:
a housing; and
a retaining mechanism movable within the housing,
wherein the retaining mechanism is movable towards a first end of the housing to (i) receive a portion of an electronic component, and (ii) retain the electronic component via a biasing of the retaining mechanism toward a second end of the housing.

2. The retaining assembly of claim 1, wherein the retaining assembly is a surface-mounted retaining assembly.

3. The retaining assembly of claim 1, wherein the housing is configured to be soldered to a printed circuit board (PCB) pad having an area less than about 20 mm².

4. The retaining assembly of claim 1, wherein the electronic component comprises an M.2 module.

5. The retaining assembly of claim 1, wherein the first end of the housing is opposite to the second end of the housing.

6. The retaining assembly of claim 1, further comprising:
a pin coupled to the first end of the housing and disposed through a hole in the retaining mechanism; and
a spring disposed over the pin and compressed when the retaining mechanism is moved towards the first end of the housing.

7. The retaining assembly of claim 6, wherein the retaining mechanism is movable in a direction that is aligned with a center longitudinal axis of the pin.

8. The retaining assembly of claim 1, wherein the retaining mechanism comprises a set of notches, and
a set of tabs of the housing engage with the notches in the retaining mechanism.

9. The retaining assembly of claim 8, wherein a region in which the set of tabs of the housing and the set of notches of the retaining mechanism engage with one another defines at least a portion of a range of movement of the retaining mechanism within the housing.

10. An electronic device, comprising:
a printed circuit board (PCB); and
a retaining assembly, comprising:
a housing; and
a retaining mechanism movable within the housing,
wherein the retaining assembly is movable towards a first end of the housing to (i) receive a portion of an electronic component, and (ii) retain the electronic component via a biasing of the retaining mechanism toward a second end of the housing.

11. The electronic device of claim 10, wherein the retaining assembly is a surface-mounted retaining assembly.

12. The electronic device of claim 10, wherein the housing is configured to be soldered to a printed circuit board (PCB) pad having an area less than about 20 mm².

13. The electronic device of claim 10, wherein the electronic component comprises an M.2 module.

14. The electronic device of claim 10, wherein the first end of the housing is opposite to the second end of the housing.

15. The electronic device of claim 10, wherein the retaining assembly further comprises:
a pin coupled to the first end of the housing and disposed through a hole in the retaining mechanism; and
a spring disposed over the pin and compressed when the retaining mechanism is moved towards the first end of the housing.

16. The electronic device of claim 15, wherein the retaining mechanism is movable in a direction that is aligned with a center longitudinal axis of the pin.

17. The electronic device of claim 10, wherein the retaining mechanism comprises a set of notches, and
a set of tabs of the housing engage with the notches in the retaining mechanism.

18. The electronic device of claim 17, wherein a region in which the set of tabs of the housing and the set of notches of the retaining mechanism engage with one another defines at least a portion of a range of movement of the retaining mechanism within the housing.

19. A retaining assembly, comprising:
a housing; and
a retaining means for retaining an electronic component, the retaining means being movable within the housing,
wherein the retaining means is movable towards a first end of the housing to (i) receive a portion of the electronic component, and (ii) retain the electronic component via a biasing of the retaining means toward a second end of the housing.

20. The retaining assembly of claim 19, wherein:
the retaining assembly is a surface-mounted retaining assembly,
the electronic component comprises an M.2 module, and
the first end of the housing is opposite to the second end of the housing.
